(19) United States
(12) Patent Application Publication
(10) Pub. No.: US 2025/0053208 A1
(43) Pub. Date: Feb. 13, 2025

(54) COMPUTING SYSTEM WITH COOLING CONFIGURATION

(71) Applicant: Samsung Electronics Co., Ltd., Suwon-si (KR)

(72) Inventors: Sungeun JO, Suwon-si (KR); Byungwoo BANG, Suwon-si (KR)

(73) Assignee: Samsung Electronics Co., Ltd., Suwon-si (KR)

(21) Appl. No.: 18/767,342

(22) Filed: Jul. 9, 2024

(30) Foreign Application Priority Data
Aug. 11, 2023 (KR) 10-2023-0105501

(51) Int. Cl. G06F 1/20; H05K 7/20

(52) U.S. Cl. CPC G06F 1/20; H05K 7/20727; H05K 7/20772

(57) ABSTRACT

A system includes a main board and sub-board units connected thereto. Each sub-board unit includes: a first sub-board connected to the main board and first chips arranged on a side of the first sub-board; a second sub-board connected to the main board and second chips arranged on a side of the second sub-board; and a cooling structure between the first sub-board and the second sub-board. The first sub-board and the second sub-board are arranged such that the side of the first sub-board and side of the second sub-board both face the cooling structure. A first region of the first sub-board defined by an outline of a first chip is directly opposite an identical second region of the second sub-board, and at least a portion of a second chip that corresponds to the first chip is outside the second region.

### CROSS-REFERENCE TO RELATED APPLICATIONS

This application claims the benefit under 35 USC § 119(a) of Korean Patent Application No. 10-2023-0105501, filed on Aug. 11, 2023, in the Korean Intellectual Property Office, the entire disclosure of which is incorporated herein by reference for all purposes.

### BACKGROUND

### 1. Field

The following description relates to a cooling system and an electronic device including the cooling system.

### 2. Description of Related Art

To perform complex calculations or increase calculation speed, a supercomputer with a super node structure has been used. Super node supercomputers have sub-boards mounted on one main board. Chips of such a supercomputer are disposed on each sub-board of the super node structure. Each chip may consume tens to hundreds of watts and may generate heat accordingly, and collectively, such chips present a significant heat dissipation problem. A structure to cool the chips is needed. For example, a water-cooling structure using a fluid with high specific heat may be applied to each sub-board. Since the sub-boards are provided on the super node structure, multiple respective cooling structures must also be provided. Furthermore, as the number of cooling structures increases, there is a problem in that the volume and weight of the entire device increase. As the volume of a device increases, there may be restrictions on the number of sub-boards that may be accommodated in a limited space. As the weight of a device increases, there may be a problem in that the sub-board and/or main board are bent or damaged due to the weight of the cooling structure. In short, in addition to their costs, liquid cooling systems impose structural design constraints on super node supercomputers.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a computing system includes: a main board; and sub-board units connected to the main board, wherein each sub-board unit includes: a first sub-board electrically connected to the main board and including first chips arranged on a side of the first sub-board; a second sub-board electrically connected to the main board and including second chips arranged on a side of the second sub-board; and a cooling structure sandwiched between the first sub-board and the second sub-board, wherein the first sub-board and the second sub-board are arranged such that the side of the first sub-board and side of the second sub-board both face the cooling structure, and wherein a first region of the first sub-board defined by an outline of a first chip, among the first chips, is directly opposite an identical second region of the second sub-board, and wherein at least a portion of a second chip, among the second chips, that corresponds to the first chip, is outside the second region.

The first chips may be arranged on the first sub-board in a first layout having a chip layout pattern, the second chips may be arranged with a second layout also having the chip layout pattern, and the first layout may have an offset along a dimension of the first sub-board that differs from an offset of the second layout along the dimension of the second sub-board.

The first chips and the second chips may have a same width and length, and a distance by which the first layout is offset along the dimension with respect to the second layout is greater than or equal to one half of the width or the length.

A layout of the second chips may be offset with respect to the same layout of the first chips in a first direction and in a second direction that is perpendicular to the first direction, the first sub-board and the second sub-board being aligned across from each other in the sub-board unit.

Each of the first chips and the second chips may have a same chip area, each first chip may only partially overlap, from a perspective perpendicular to the sides of the first and second sub-boards, a respectively corresponding second chip, and such overlaps may have an area less than or equal to one half of the chip area.

From a perspective perpendicular to the sides of the first and second sub-boards, the none of the second chips may be overlapped by any of the first chips.

The first chips and the second chips may be respectively disposed on the first sub-board and the second sub-board to form a same chip layout pattern.

The chip layout pattern may be a grid pattern.

Viewed from a direction perpendicular to the sides of the first and second sub-boards, each of the second chips may overlap a respectively corresponding first chip and also overlap with non-chip space on the first sub-board.

The first chips and the second chips may be instances of a same chip, the first sub-board may perform same computing functions as the second sub-board, and the number of first chips may be the same as the number of second chips.

The first chips may be arranged to form first chip groups, each first chip group having at least two first chips disposed adjacently, and the second chips may be arranged to form second chip groups, each second chip group having at least two second chips disposed adjacently.

At least a partial region of a second chip group is arranged not to overlap with a corresponding first chip group as viewed from a direction perpendicular to the sides of the first and second sub-boards.

The first sub-board and the second sub-board may be configured to share the cooling structure, wherein tops of the first chips may face the cooling structure, and wherein tops of the second chips may also face the cooling structure.

The cooling structure may be in contact with the tops of the first chips and with the tops of the second chips to cool the first chips and the second chips.

The cooling structure may include a flow path for a liquid or gaseous cooling fluid to flow or a heat exchange member for heat exchange.

In another aspect, an electronic device includes: a main board; and sub-board units connected to the main board, each sub-board unit including: a cooling structure disposed between a first sub-board and a second sub-board; the first sub-board electrically connected to the main board and including first chips arranged on a surface of the first sub-board that faces the cooling structure and that faces the second sub-board; the second sub-board electrically connected to the main board and including second chips disposed on a surface of the second sub-board that faces the cooling structure and that faces the first sub-board; and wherein the first sub-board and the second sub-board are arranged such that tops of the first chips and tops of the second chips face the cooling structure, and wherein, from a direction perpendicular to the first and second sub-boards, at least a partial region a second chip among the second chips does not overlap with any of the first chips.

From the direction perpendicular to the first and second sub-boards the second chips may respectively correspond, positionally, to the first chips, and each second chip has at least a portion thereof that does not overlap its corresponding first chip.

The first chips and the second chips may each have the same area, and the area of each of regions where the first and second chips only partially overlap is less than or equal to one half of the area of each of the first and second chips.

The first chips and the second chips may be respectively arranged on the first sub-board and the second sub-board with a same grid pattern, and from the direction perpendicular to the sides of the first and second sub-boards, each of the second chips overlaps with at least some space of the first sub-board that does not contain any of the first chips.

The electronic device may be a supercomputer or a server.

Other features and aspects will be apparent from the following detailed description, the drawings, and the claims.

### BRIEF DESCRIPTION OF THE DRAWINGS

FIG. 1 illustrates an example of a cooling system, according to one or more embodiments.

FIG. 2 illustrates an example of the cooling system, according to one or more embodiments.

FIG. 3A illustrates an example of a first sub-board and a second sub-board viewed from the front, according to one or more embodiments.

FIG. 3B illustrates an example of a first sub-board and a second sub-board viewed from the front, according to one or more embodiments.

FIG. 3C illustrates an example of a first sub-board and a second sub-board viewed from the front, according to one or more embodiments.

FIG. 3D illustrates an example of a first sub-board and a second sub-board viewed from the front, according to one or more embodiments.

FIG. 3E illustrates an example of a first sub-board and a second sub-board viewed from the front, according to one or more embodiments.

FIG. 3F illustrates an example of a first sub-board and a second sub-board viewed from the front, according to one or more embodiments.

FIG. 3G illustrates an example of a first sub-board and a second sub-board viewed from the front, according to one or more embodiments.

FIG. 3H illustrates an example of a first sub-board and a second sub-board viewed from the front, according to one or more embodiments.

FIG. 3I illustrates an example of a first sub-board and a second sub-board viewed from the front, according to one or more embodiments.

FIG. 3J illustrates an example of a first sub-board and a second sub-board viewed from the front, according to one or more embodiments.

FIG. 3K illustrates an example of a first sub-board and a second sub-board viewed from the front, according to one or more embodiments.

FIG. 3L illustrates an example of a first sub-board and a second sub-board viewed from the front, according to one or more embodiments.

Throughout the drawings and the detailed description, unless otherwise described or provided, the same or like drawing reference numerals will be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

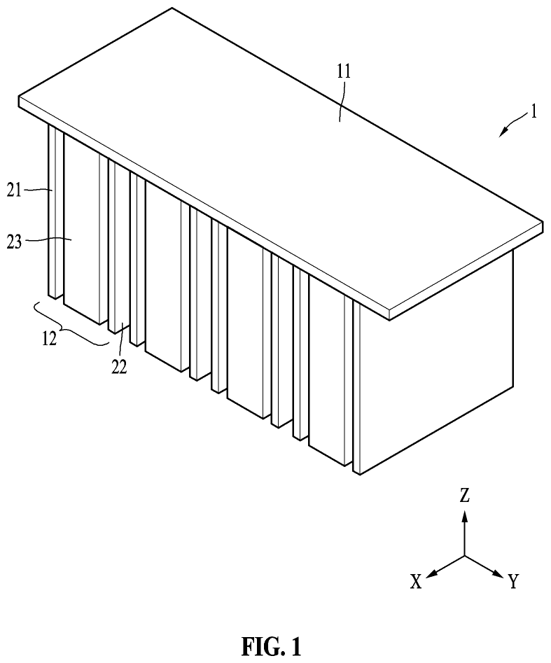

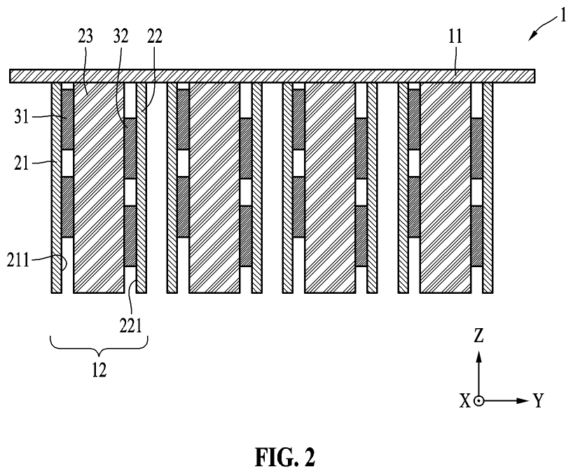

FIG. 1 illustrates an example of a cooling system, according to one or more embodiments. FIG. 2 illustrates an example of the cooling system, according to one or more embodiments.

Referring to FIGS. 1 and 2, a cooling system 1 may be included in an electronic device and may cool each component (e.g., a main board 11 and/or sub-boards 21 and 22) of the electronic device using a cooling structure 23. For example, the electronic device may be a supercomputer with a super node structure. However, this is an example, and the electronic device may include a high-performance computing (HPC) device or a server.

The cooling system 1 may include the main board 11 and sub-board units 12. FIGS. 1 and 2 illustrate schematic features; the shape, structure, number and/or location of the main board 11 and the sub-board units 12 are not limited to those shown in the drawings.

The main board 11 may have a configuration to which the sub-board units 12 are connected. For example, the plurality of sub-boards 21 and 22 may be electrically and/or physically connected to the main board 11. The main board 11 may exchange an electrical signal with the plurality of sub-boards 21 and 22. In some embodiments, the main board 11 may include a central processing unit (CPU) and the sub-boards may be accelerator boards controlled by the CPU of the main board 11.

Each sub-board unit 12 may be connected to the main board 11. There may be multiple sub-board units 12. The sub-board units 12 may be disposed on the main board 11 to be spaced apart from each other in at least one direction (e.g., the Y direction or a lengthwise direction of the main board 11). For example, a sub-board unit 12 may be connected to the main board 11 such that it is substantially perpendicular to the main board 11.

A sub-board unit 12 may include a first sub-board 21, a second sub-board 22, and a cooling structure 23.

The first sub-board 21 may be electrically connected to the main board 11. The first sub-board 21 may be physically connected to/with the main board 11 to be substantially perpendicular to the main board 11. The first sub-board 21 may form one node in a super node structure comprised in the electronic device. The first sub-board 21 may include first chips 31 (dark shading). A first chip 31 may include a circuit and/or memory for calculations. The plurality of first chips 31 may be disposed on at least one side 211 of the first sub-board 21, which may be a side facing a cooling structure in the sub-board unit 12 to which the first chip 31 belongs. For example, multiple first chips 31 may be disposed on a first sub-board 21 to form a predetermined pattern or layout of the first chips 31. For example, the first chips 31 may be disposed in a grid pattern on the plane/side of the first sub-board 21 to which they belong. However, this is an example, and the pattern of the first chips 31 is not limited thereto.

The second sub-board 22 may also be electrically connected to the main board 11. The second sub-board 22 may be physically connected to/with the main board 11 to be substantially perpendicular to the main board 11. The second sub-board 22 may form one node in the super node structure. The second sub-board 22 may include second chips 32. The second chip 32 may include a circuit and/or memory for calculations (which may be the same as the first chips 31). The second chips 32 may be disposed on at least one side 221 of the second sub-board 22, for example, on a side/plane of the second sub-board 22 facing the interior of the corresponding sub-board unit 12. The second chips 32 may be disposed on the second sub-board 22 to form a predetermined pattern. For example, the second chips 32 may be disposed in a grid or rectilinear pattern. However, this is an example, and the pattern of the second chips 32 is not limited thereto.

The first sub-board 21 and the second sub-board 22 may be disposed spaced apart from each other and substantially parallel to each other. The first sub-board 21 and the second sub-board 22 may be disposed such that the first chips 31 and the second chips 32 face each other. For example, the first sub-board 21 and the second sub-board 22 may be disposed so that one side 211 of the first sub-board 21 (having the first chips 31 mounted thereon) and one side 221 of the second sub-board 22 (having the second chips 32 mounted thereon) face each other.

The cooling structure 23 may be disposed between the first sub-board 21 and the second sub-board 22, the three forming a sandwich structure. The cooling structure 23 may be configured to cool the first sub-board 21 and the second sub-board 22. The first sub-board 21 and the second sub-board 22 may be configured to share the cooling structure 23 disposed therebetween. The first sub-board 21 and the second sub-board 22 may be disposed such that the first chip 31 and the second chip 32 both face the cooling structure 23. For example, the cooling structure 23 may be adjacent to or in contact with the first chips 31 and the second chips 32 to cool the first chips 31 and the second chips 32. The cooling structure 23 may include a flow path for a cooling fluid to flow and/or a heat exchange member for heat exchange. However, this is an example, and the type of the cooling structure 23 is not limited thereto. Put another way, the cooling structure 23 may be arranged to absorb heat from the chips of the sub-boards that it is sandwiched between (possibly in contact with the chips) and may transfer that heat to a gas/liquid flowing through the cooling structure 23.

Since the first sub-board 21 and the second sub-board 22 are configured to share the cooling structure 23 disposed therebetween, the total volume and/or weight of the cooling system 1 may be reduced. For example, a smaller number of total cooling structures 23 may be used when pairs of sub-boards 21 and 22 share one cooling structure 23, compared to when each sub-board has its own respective cooling structure. For example, compared to a cooling system having eight sub-boards cooled by eight respective cooling structures, the cooling system 1 may include eight sub-boards 21 and 22 and four cooling structures 23. Accordingly, because the number of cooling structures 23 connected to the main board 11 and/or the sub-boards 21 and 22 is reduced, the space occupied by the cooling system 1 may be reduced and also the phenomenon that the main board 11 and/or the sub-boards 21 and 22 are bent or damaged due to the weight of the cooling structures 23 may be reduced.

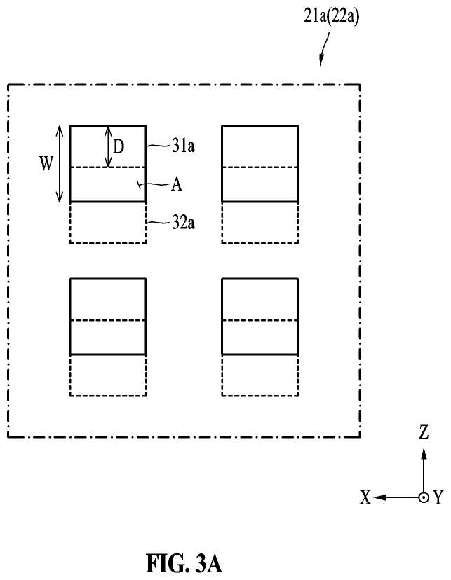

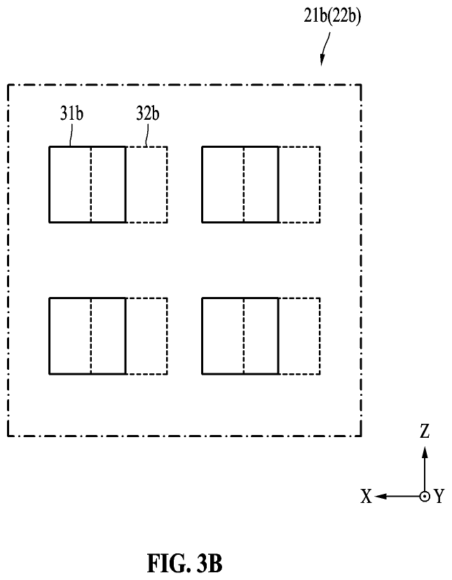

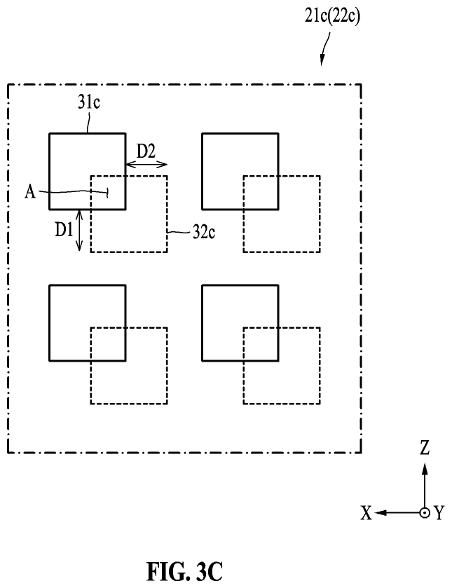

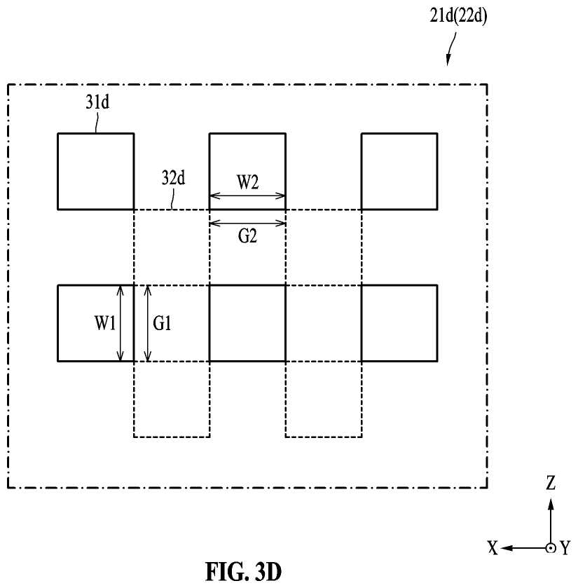

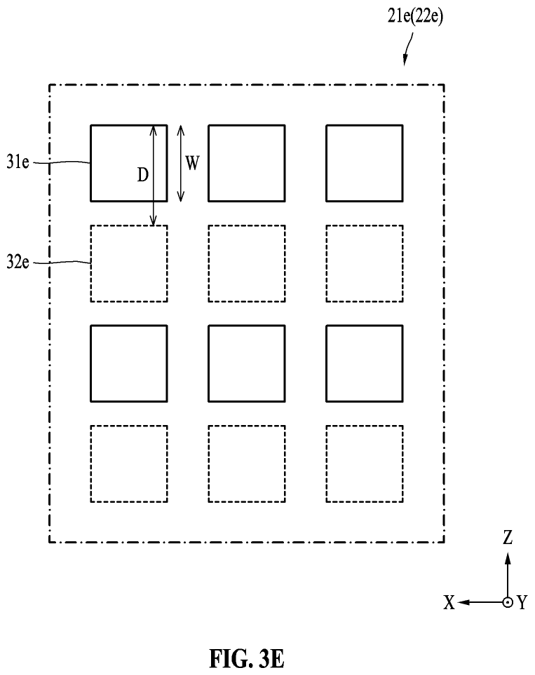

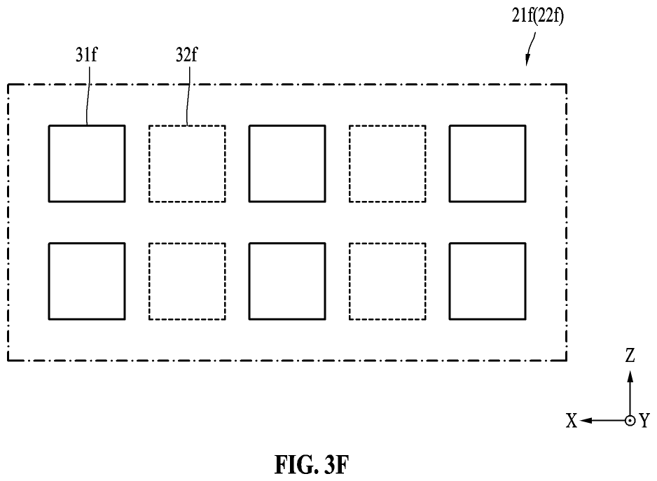

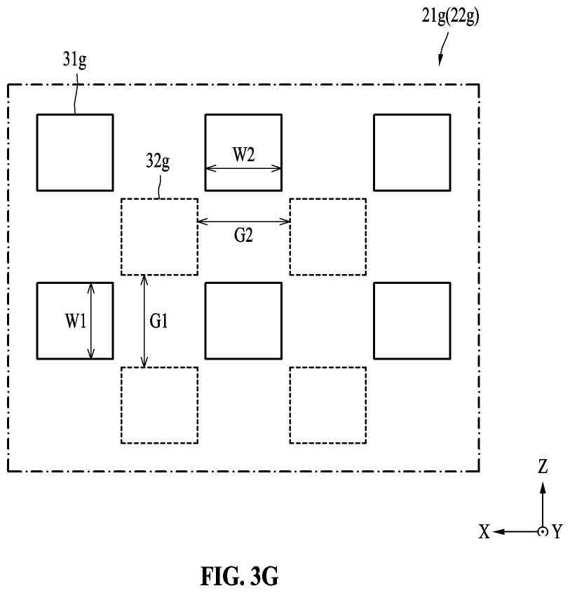

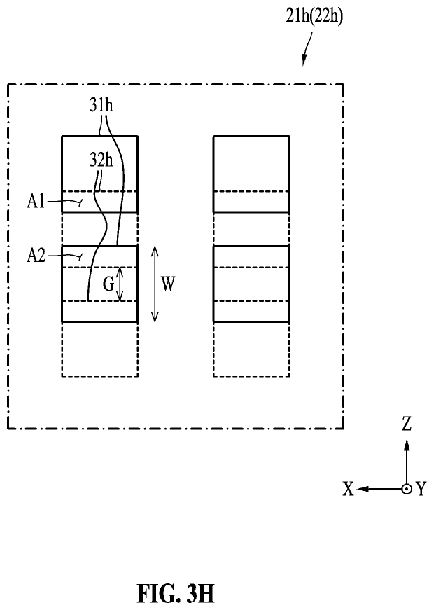

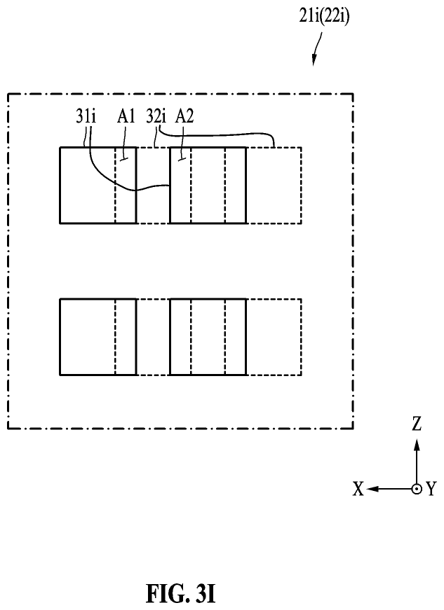

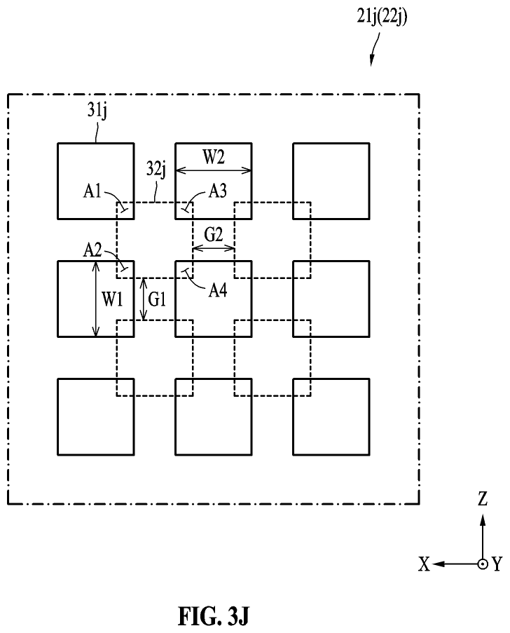

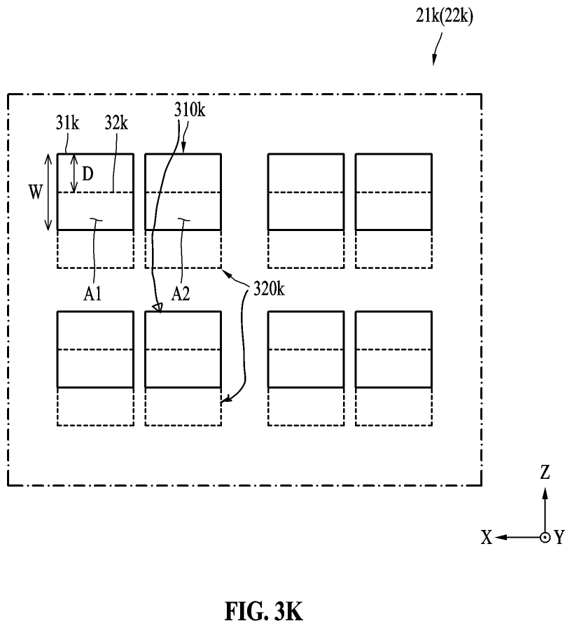

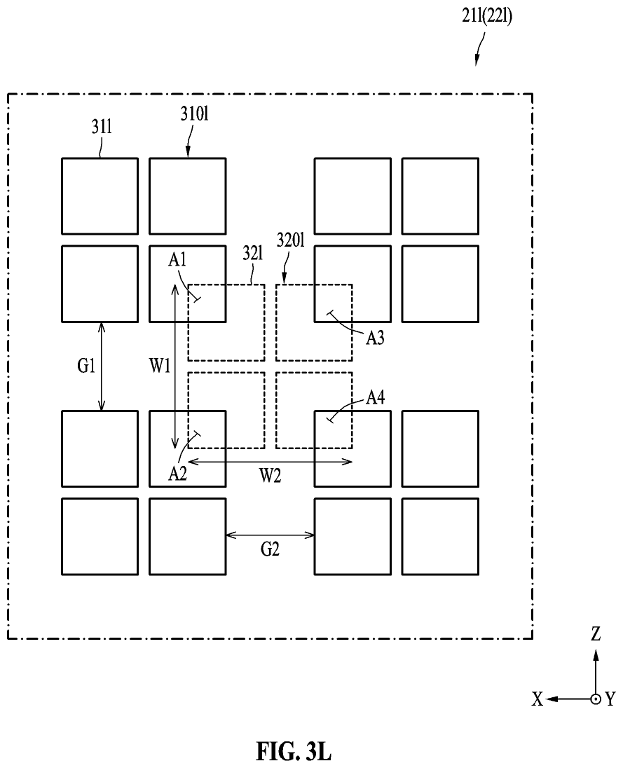

When the first sub-board 21 and the second sub-board 22 are viewed from the front (e.g., from the +Y direction, e.g., FIG. 3A)), at least a partial region of a partial second chip 32 (of the second chips 32) may be disposed not to overlap with a first chip 31 (insofar as their respective sub-boards are aligned). This is described in detail below.

FIG. 3A illustrates an example of a first sub-board 21a and a second sub-board 22a viewed from the front, according to one or more embodiments. In FIG. 3A, a first chip 31a is shown as a solid line and a second chip 32a is shown as a dashed line to show the relative locations of the first chip 31a and the second chip 32a when their respective sub-boards (in a sub-board unit 12) are aligned.

Referring to FIG. 3A, when the first sub-board 21a and the second sub-board 22a are viewed from the front (e.g., from the +Y direction) and are aligned, the first and second chips 31a, 32a may be arranged on their respective sub-boards such that only a partial region A of the second chip 32a overlaps with the first chip 31a and the remaining region of the second chip 32a does not overlap with the first chip 31a. For example, when the first sub-board 21a and the second sub-board 22a are aligned and viewed from the front (e.g., when viewed from the +Y direction), the second chip 32a may be arranged to be offset (e.g., disposed to be misaligned with each other) with respect to the first chip 31a in a first direction (e.g., the −Z direction). For example, a distance D by which the second chip 32a is offset with respect to the first chip 31a in the first direction (e.g., the −Z direction) may be greater than or equal to ½, ⅔, or ¾ of a width W (or the width of the second chip 32a in the first direction (e.g., the −Z direction)) of the first chip 31a in the first direction (e.g., the −Z direction). For example, the distance D by which the second chip 32a is offset with respect to the first chip 31a in the first direction (e.g., the −Z direction) may be less than the width W (or the width of the second chip 32a in the first direction (e.g., −Z direction)) of the first chip 31a in the first direction (e.g., the −Z direction). For example, the area of a region A where the first chip 31a and the second chip 32a overlap with each other may be less than or equal to ½, ⅓, ¼ of the area of the first chip 31a (or the area of the second chip 32a). According to this structure, the first chip 31a and the second chip 32a are disposed to be offset from each other based on a cooling structure (e.g., the cooling structure 23 in FIG. 2), so the cooling structure 23 may evenly contact the first chip 31a and the second chip 32a over both surfaces of the cooling structure 23. As the regions where the cooling structure 23 contacts the first chip 31a and the second chip 32a respectively are evenly distributed, the cooling structure 23 may smoothly cool the first chip 31a and the second chip 32a. For example, when the cooling fluid flows into the cooling structure 23, the cooling fluid may evenly cool the first chip 31a and the second chip 32a while alternately contacting the first chip 31a and the second chip 32a by at least a partial section. As used herein, “fluid” refers to both liquid and gaseous fluids. As a result, as the first chip 31a and the second chip 32a are disposed to be offset from each other, the first chip 31a and the second chip 32a may be smoothly cooled while the first sub-board 21a and the second sub-board 22a share one cooling structure 23.

FIG. 3B illustrates an example of a first sub-board 21b and a second sub-board 22b viewed from the front, according to one or more embodiments. In FIG. 3B, a first chip 31b is shown as a solid line and a second chip 32b is shown as a dashed line to show the relative locations of the first chip 31b and the second chip 32b when their respective sub-boards (in a sub-board unit 12) are aligned.

Referring to FIG. 3B, when the first sub-board 21b and the second sub-board 22b are viewed from the front (e.g., from the +Y direction) and aligned, the first and second chips 32a, 32b may be arranged on their respective sub-boards such that the second chip 32b is offset (e.g., not aligned) with respect to the first chip 31b in a second direction (e.g., the −X direction). The example shown in FIG. 3B may be understood as an example in which the offset direction is different from the example shown in FIG. 3A. The description of the example according to FIG. 3A may be applied to the example according to FIG. 3B.

FIG. 3C illustrates an example of a first sub-board 21c and a second sub-board 22c viewed from the front, according to one or more embodiments. In FIG. 3C, a first chip 31c is shown as a solid line and a second chip 32c is shown as a dashed line to show the relative locations of the first chip 31c and the second chip 32c on their respective sub-boards (in a sub-board unit 12) are aligned.

Referring to FIG. 3C, when the first sub-board 21c and the second sub-board 22c are aligned and viewed from the front (e.g., from the +Y direction), only a partial region A of the second chip 32c overlaps with the first chip 31c and the remaining region of the second chip 32c does not overlap with the first chip 31c. For example, when the first sub-board 21c and the second sub-board 22c are aligned and viewed from the front (e.g., when viewed from the +Y direction), the second chip 32c are offset (e.g., not aligned with each other) with respect to the first chip 31c in at least the first direction (e.g., the −Z direction) and the second direction (e.g., the −X direction) that is perpendicular to the first direction. For example, for a distance D1 by which the second chip 32c is offset with respect to the first chip 31c in the first direction (e.g., the −Z direction) and for a distance D2 by which the second chip 32c is offset with respect to the first chip 31c in the second direction (e.g., the −X direction), distances D1 and D2 may be the same or different. For example, the area of a region A where the first chip 31c and the second chip 32c overlap with each other may be less than or equal to ½, ⅓, or ¼ of the area of the first chip 31c (or the area of the second chip 32c).

FIG. 3D illustrates an example of a first sub-board 21d and a second sub-board 22d viewed from the front, according to one or more embodiments. In FIG. 3D, a first chip 31d is shown as a solid line and a second chip 32d is shown as a dashed line to show the relative locations of the first chip 31d and the second chip 32d when their respective sub-boards (in a sub-board unit 12) are aligned.

Referring to FIG. 3D, when the first sub-board 21d and the second sub-board 22d are aligned and viewed from the front (e.g., when viewed from the +Y direction), the first and second chips 31d, 32d may be arranged on their respective sub-boards such that its counterpart second chip 32d does not to overlap with the first chip 31d. For example, when the first sub-board 21d and the second sub-board 22d are aligned and viewed from the front (e.g., from the +Y direction), each of the second chips 32d may be disposed to overlap with each other on an empty space of a pattern formed by the first chips 31d. That is to say, the chip layout pattern on one of the sub-boards of a sub-board unit 12 may be such that the chip layout pattern on the other of the sub-boards of the sub-board unit 12 may complement each other in terms of chip and non-chip space; each chip on one sub-board may oppose non-chip space on the opposing sub-board. For example, the plurality of first chips 31d and the plurality of second chips 32d may be substantially disposed in a checkered pattern (or diamond pattern). For example, a gap G1 or G2 between two adjacent second chips 32d may be substantially the same as a width W1 or W2 of the first chip 31d. For example, the gap G1 between two adjacent second chips 32d in the first direction (e.g., the Z direction) may be substantially the same as the width W1 of the first chip 31d in the first direction (e.g., the Z direction). For example, the gap G2 between two adjacent second chips 32d in the second direction (e.g., the X direction) may be substantially the same as the width W2 of the first chip 31d in the second direction (e.g., the X direction).

FIG. 3E illustrates an example of a first sub-board 21e and a second sub-board 22e aligned and viewed from the front, according to one or more embodiments. In FIG. 3E, a first chip 31e is shown as a solid line and a second chip 32e is shown as a dashed line to show the relative locations of the first chip 31e and the second chip 32e when their respective sub-boards are aligned in a sub-board unit.

Referring to FIG. 3E, when the first sub-board 21e and the second sub-board 22e are viewed from the front (e.g., from the +Y direction), the second chip 32e may be arranged to not overlap with the first chip 31e. For example, when the first sub-board 21e and the second sub-board 22e are viewed from the front (e.g., when viewed from the +Y direction), each of the second chips 32e may be arranged to overlap with respective empty spaces in a layout pattern of the first chips 31e. For example, when the first sub-board 21e and the second sub-board 22e are aligned and viewed from the front (e.g., when viewed from the +Y direction), the second chip 32e may be offset (e.g., not aligned) with respect to a corresponding first chip 31e in the first direction (e.g., the −Z direction). For example, a distance D by which the second chip 32e is offset with respect to the first chip 31e in the first direction (e.g., the −Z direction) may be greater than a width W of the first chip 31e in the first direction (e.g., the Z direction) (or the width of the second chip 32e in the first direction (e.g., the Z direction)).

FIG. 3F illustrates an example of a first sub-board 21f and a second sub-board 22f viewed from the front, according to one or more embodiments. In FIG. 3F, a first chip 31f is shown as a solid line and a second chip 32f is shown as a dashed line to show the relative locations of the first chip 31f and the second chip 32f when their respective sub-boards of a sub-board unit are aligned.

Referring to FIG. 3F, when the first sub-board 21f and the second sub-board 22f are aligned with each other and viewed from the front (e.g., from the +Y direction), the second chip 32f may be arranged such that it is offset (e.g., not aligned) with respect to the corresponding first chip 31f in the second direction (e.g., the −X direction). The example shown in FIG. 3F is an example similar to the example shown in FIG. 3E, but where the offset direction is different from that of the example of FIG. 3E. The description of the example according to FIG. 3E is generally applicable to the example according to FIG. 3F.

FIG. 3G illustrates an example of a first sub-board 21g and a second sub-board 22g viewed from the front, according to one or more embodiments. In FIG. 3G, a first chip 31g is shown as a solid line and a second chip 32g is shown as a dashed line to show the relative locations of the first chip 31g and the second chip 32g when their respective sub-boards of a sub-board unit are aligned.

Referring to FIG. 3G, when the first sub-board 21g and the second sub-board 22g are aligned with each other and viewed from the front (e.g., when viewed from the +Y direction), the second chip 32g may be arranged so as to not overlap with the corresponding first chip 31g. For example, when the first sub-board 21g and the second sub-board 22g are aligned with each other and viewed from the front (e.g., from the +Y direction), each of the second chips 32g may be arranged to overlap with corresponding empty spaces in a pattern formed by the first chips 31g. For example, a gap G1 or G2 between two adjacent second chips 32g may be greater than a width W1 or W2 of the corresponding first chip 31g. For example, the gap G1 between two adjacent second chips 32g in the first direction (e.g., the Z direction) may be greater than the width W1 of the first chip 31g in the first direction (e.g., the Z direction). For example, the gap G2 between two adjacent second chips 32g in the second direction (e.g., the X direction) may be greater than the width W2 of the first chip 31g in the second direction (e.g., the X direction). Put another way, the chips of the respective sub-boards may have a same layout pattern (e.g., grid, rectilinear, diamond, etc.), the layout pattern may have chip and non-chip areas, and the chip layout of one sub-board in a sub-board unit (a cooling element sandwiched between the sub-boards) may be offset relative to the chip layout of the other sub-board such that chip space on one sub-board aligns with non-chip space on the opposing sub-board.

FIG. 3H illustrates an example of a first sub-board 21h and a second sub-board 22h viewed from the front, according to one or more embodiments. In FIG. 3H, a first chip 31h is shown as a solid line and a second chip 32h is shown as a dashed line to show the relative locations of the first chip 31h and the second chip 32h when their respective sub-boards are aligned in a sub-board unit.

Referring to FIG. 3H, when the first sub-board 21h and the second sub-board 22h of a sub-board unit are aligned and viewed from the front (e.g., the +Y direction), the second chip 32h may be arranged to partially overlap with the corresponding first chips 31h at respective regions A1 and A2 thereof and to not overlap the first chips 31h at the remaining region of the second chip 32h. For example, when the first sub-board 21h and the second sub-board 22h are aligned and viewed from the front (e.g., from the +Y direction), the second chip 32h may be arranged such that it is offset (not aligned with) with the corresponding first chips 31h in the first direction (e.g., the −Z direction); the first region A1 and the second region A2 may overlap with the two adjacent first chips 31h, respectively. For example, a gap G between two adjacent second chips 32h in the first direction (e.g., the Z direction) may be less than a width W of the first chip 31h in the first direction (e.g., the Z direction). For example, the total area of the regions A1 and A2 where the first chips 31h and the second chip 32h overlap with each other may be less than or equal to ½, ⅓, or ¼ of the area of the first chip 31h (or the area of the second chip 32h).

FIG. 3I illustrates an example of a first sub-board 21i and a second sub-board 22i viewed from the front, according to one or more embodiments. In FIG. 3I, a first chip 31i is shown as a solid line and corresponding second chips 32i are shown as a dashed line to show the relative locations of the first chip 31i and the second chips 32i when their respective sub-boards are aligned in a sub-board unit.

Referring to FIG. 3I, when the first sub-board 21i and the second sub-board 22i are viewed from the front (e.g., when viewed from the +Y direction) and their sub-boards are aligned in a sub-board unit, only partial regions A1 and A2 of the second chip 32i may overlap with the first chips 31i and the remaining region of the second chip 32i may be disposed not to overlap with the first chips 31i. For example, when the first sub-board 21i and the second sub-board 22i are viewed from the front (e.g., from the +Y direction) as aligned in their sub-board unit, the second chip 32i may be offset (e.g., not aligned) with respect to the first chips 31i in the second direction (e.g., the −X direction) so that the first region A1 and the second region A2 overlap with the two adjacent first chips 31i, respectively. The example shown in FIG. 3I similar to the example shown in FIG. 3H, but the offset direction is different. Otherwise, the description of FIG. 3H generally applies to the example of FIG. 3I.

FIG. 3J illustrates an example of a first sub-board 21j and a second sub-board 22j viewed from the front, according to one or more embodiments. In FIG. 3J, a first chip 31j is shown as a solid line and a second chip 32j is shown as a dashed line to show the relative locations of the first chip 31j and the second chip 32j as their sub-boards are aligned in a sub-board unit.

Referring to FIG. 3J, when the first sub-board 21j and the second sub-board 22j are aligned in their sub-board unit and viewed from the front (e.g., from the +Y direction), the second chip 32j may be arranged such that only partial regions A1, A2, A3, and A4 of the second chip 32j overlap with the respective first chips 31j and the remaining region of the second chip 32j does not overlap with the first chips 31j. For example, when the first sub-board 21j and the second sub-board 22j are aligned and viewed from the front (e.g., from the +Y direction), the second chip 32j may be arranged to be offset (e.g., disposed to be misaligned with each other) with respect to the first chips 31j in the first direction (e.g., the −Z direction) and in the second direction (e.g., the −X direction, which is perpendicular to the first direction) so that the first region A1, the second region A2, the third region A3, and the fourth region A4 overlap with corresponding four adjacent first chips 31j, respectively. For example, a gap G1 or G2 between two adjacent second chips 32j may be less than a width W1 or W2 of the first chip 31j. For example, the gap G1 between two adjacent second chips 32j in the first direction (e.g., the Z direction) may be less than the width W1 of the first chip 31j in the first direction (e.g., the Z direction). For example, the gap G2 between two adjacent second chips 32j in the second direction (e.g., the X direction) may be less than the width W2 of the first chip 31j in the second direction (e.g., the X direction). For example, the total area of the first, second, third, and fourth regions A1, A2, A3, and A4 where the first chip 31j and the second chip 32j overlap with each other may be less than or equal to ½, ⅓, or ¼ of the area of the first chip 31j (or the area of the second chip 32j).

FIG. 3K illustrates an example of a first sub-board 21k and a second sub-board 22k viewed from the front, according to one or more embodiments. In FIG. 3K, a first chip 31k is shown as a solid line and a second chip 32k is shown as a dashed line to show the relative locations of the first chip 31k and the second chip 32k in their respective sub-boards as aligned in a sub-board unit.

Referring to FIG. 3K, the first chips 31k may form first chip groups 310k on which at least two first chips 31k are disposed adjacently. For example, a first chip group 310k may include two first chips 31k disposed adjacently in the first direction (e.g., the Z direction), as shown in FIG. 3K. The first chip groups 310k may be disposed to be spaced apart from each other. For example, the first chip groups 310k may be disposed to form a predetermined pattern (e.g., a grid pattern).

The second chips 32k may form second chip groups 320k; each second chip group 320k may have at least two second chips 32k arranged adjacently to each other. For example, the second chip groups 320k may be formed in the same manner (e.g., the number and/or disposition of chips) as the first chip groups 310k. For example, each second chip group 320k may include two second chips 32k arranged adjacently in the first direction (e.g., the Z direction), as shown in FIG. 3K. The second chip groups 320k may be arranged to be spaced apart from each other. For example, the second chip groups 320k may be arranged to form a predetermined pattern (e.g., a grid pattern).

When the first sub-board 21k and the second sub-board 22k are aligned with each other and viewed from the front (e.g., when viewed from the +Y direction), a second chip group 320k may be arranged to have a partial region thereof not overlap with a corresponding first chip group 320k. For example, when the first sub-board 21k and the second sub-board 22k are aligned and viewed from the front (e.g., from the +Y direction), only partial regions A1 and A2 of the second chip group 320k may overlap with the first chip group 310k and the remaining region of the second chip group 320k may not overlap with the first chip group 310k. For example, when the first sub-board 21k and the second sub-board 22k are aligned and viewed from the front (e.g., when viewed from the +Y direction), the second chip group 320k may be arranged such that it is offset (e.g., not aligned) with respect to the first chip group 310k in the first direction (e.g., the −Z direction). For example, a distance D by which the second chip group 320k is offset with respect to the corresponding first chip group 310k in the first direction (e.g., the −Z direction) may be greater than or equal to ½, ⅓, or ¾ of a width W of the first chip 31k in the first direction (e.g., the Z direction) (or the width of the second chip 32k in the first direction (e.g., the −Z direction)). For example, the distance D by which the second chip group 320k is offset with respect to the first chip group 310k in the first direction (e.g., the −Z direction) may be less than the width W of the first chip group 310k in the first direction (e.g., the Z direction) (or the width of the second chip group 320k in the first direction (e.g., the Z direction)). For example, the total area of the regions A1 and A2 where the first chip group 310k and the second chip group 320k overlap with each other may be less than or equal to ½, ⅓, or ¼ of the total area of the first chip group 310k (or the total area of the second chip group 320k).

FIG. 3L illustrates an example of a first sub-board 21l and a second sub-board 22l viewed from the front, according to one or more embodiments. In FIG. 3L, a first chip 31l is shown as a solid line and a second chip 32l is shown as a dashed line to show the relative locations of the first chip 31l and the second chip 32l on their respective sub-boards in a sub-board unit.

Referring to FIG. 3L, first chips 31l may form first chip groups 310l in which at least two first chips 31l are disposed adjacently. For example, the first chip group 310l may include four first chips 31l; two arranged adjacently in the first direction (e.g., the Z direction) and two arranged adjacently in the second direction (e.g., the X direction), which is perpendicular to the first direction. The first chip groups 310l may be spaced apart from each other. For example, the first chip groups 310l may be disposed to form a predetermined pattern (e.g., a grid pattern of chip groups).

Similarly, the second chips 32l may form second chip groups 320l on which at least two second chips 32l are disposed adjacently. For example, the second chip groups 320l may be formed in the same manner (e.g., the number and/or disposition of chips) as the first chip groups 310l. For example, a second chip group 320l may include two second chips 32l arranged adjacent to each other in the first direction (e.g., the Z direction) and the second direction (e.g., the X direction), which is perpendicular to the first direction, as shown in FIG. 3L. The second chip groups 320l may be arranged to be spaced apart from each other. For example, the second chip groups 320l may be arranged to form a predetermined pattern (e.g., a grid pattern).

When the first sub-board 21l and the second sub-board 22l are viewed from the front (e.g., from the +Y direction), a second chip group 320l may be arranged so as to not overlap with a corresponding first chip group 310l. For example, when the first sub-board 21l and the second sub-board 22l are viewed from the front (e.g., from the +Y direction), only partial regions A1, A2, A3, and A4 of the second chip group 320l may overlap the first chip group 310l and the remaining region of the second chip group 320l may not overlap with the first chip group 310l. For example, when the first sub-board 21l and the second sub-board 22l are viewed from the front (e.g., when viewed from the +Y direction), the second chip group 320l may be arranged to be offset (e.g., not aligned) with respect to the first chip group 310l in the first direction (e.g., the −Z direction) and the second direction (e.g., the −X direction), which is perpendicular to the first direction. For example, a gap G1 or G2 between two adjacent first chip groups 310l may be less than a width W1 or W2 of the second chip group 320l. For example, the gap G1 between two adjacent first chip groups 310l in the first direction (e.g., the Z direction) may be less than the width W1 of the second chip group 320l in the first direction (e.g., the Z direction). For example, the gap G2 between two adjacent first chip groups 310l in the second direction (e.g., the X direction) may be less than the width W2 of the second chip group 320l in the second direction (e.g., the X direction).

In the description of the arrangement patterns of first chips and second chips with reference to FIGS. 3A to 3L, for convenience of description, a partial region of a first sub-board and a second sub-board is shown in the drawings but one of ordinary skill in the art will understand that the first chips and the second chips are respectively arranged on the remaining region of the first sub-board and the second sub-board in substantially the same pattern as the pattern shown in each drawing. That is, the chip layout patterns shown in FIGS. 3A to 3L may extend further than shown. In addition, although in FIGS. 3A to 3L the first chips and the second chips are described as having substantially the same size, this is but an example; the first chips and the second chips may have different sizes. The arrangement methods of the first chips and the second chips are not limited to those described with reference to FIGS. 3A to 3L and at least a partial region of the first chip and the second chip may be disposed in various methods without overlapping with each other. For example, the first chip and the second chip may be arranged with combinations of the methods described with reference to FIGS. 3A through 3L. Moreover, the first chip groups and the second chip groups described with reference to FIGS. 3K to 3L may themselves be arranged with the substantially same methods/patterns as the individual chip methods/patterns described with reference to FIGS. 3A to 3J.

In some embodiments, the first and second sub-boards in a sub-board unit may be, functionally, substantially equivalent. That is, each sub-board may be “swappable” with each other in terms of function. For example, the first chips on a first sub-board may be the same as the second chips on a second sub-board paired (in a sub-board unit) with the first sub-board. For example, if the first sub-board is an accelerator board for performing a given set of artificial intelligence operations, the second sub-board may implement the same set of artificial intelligence operations; the first and second chips may be instances of the same chip (e.g., a same digital signal processor, a same graphics processing unit, a same neural processor, a same computing-in-memory chip, etc.) and may be arranged with the same architecture, may have the same interface to the main board 11, may have the same controller (if any), may have the same bus and bus connections, and so forth. In other words, the sub-boards in a sub-board unit may be clones or same instances (functionally “swappable”) but may have different chip layouts as described above.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

The computing apparatuses, the electronic devices, the processors, the memories, the displays, the information output system and hardware, the storage devices, and other apparatuses, devices, units, modules, and components described herein with respect to FIGS. 1-3L are implemented by or representative of hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The apparatus illustrated in FIGS. 1-3L are computing hardware, for example, one or more processors or computers. While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. A computing system comprising:
a main board; and
sub-board units connected to the main board,
wherein each sub-board unit comprises:
a first sub-board electrically connected to the main board and comprising first chips arranged on a side of the first sub-board;
a second sub-board electrically connected to the main board and comprising second chips arranged on a side of the second sub-board; and
a cooling structure sandwiched between the first sub-board and the second sub-board,
wherein the first sub-board and the second sub-board are arranged such that the side of the first sub-board and side of the second sub-board both face the cooling structure, and
wherein a first region of the first sub-board defined by an outline of a first chip, among the first chips, wherein the first region is directly opposite an identical second region of the second sub-board, and wherein at least a portion of a second chip, among the second chips, that corresponds to the first chip, is outside the second region.

2. The computing system of claim 1, wherein the first chips are arranged on the first sub-board in a first layout having a chip layout pattern, wherein the second chips are arranged with a second layout also having the chip layout pattern, and wherein the first layout has an offset along a dimension of the first sub-board that differs from an offset of the second layout along the dimension of the second sub-board.

3. The computing system of claim 2, wherein the first chips and second chips have a same width and length, and wherein a distance by which the first layout is offset along the dimension with respect to the second layout is greater than or equal to one half of the width or the length.

4. The computing system of claim 1, wherein a layout of the second chips is offset with respect to the same layout of the first chips in a first direction and in a second direction that is perpendicular to the first direction, the first sub-board and the second sub-board being aligned across from each other in the sub-board unit.

5. The computing system of claim 1, wherein each of the first chips and the second chips have a same chip area, wherein each first chip only partially overlaps, from a perspective perpendicular to the sides of the first and second sub-boards, a respectively corresponding second chip, and wherein such overlaps have an area less than or equal to one half of the chip area.

6. The computing system of claim 1, wherein, from a perspective perpendicular to the sides of the first and second sub-boards, the none of the second chips are overlapped by any of the first chips.

7. The computing system of claim 1, wherein the first chips and the second chips are respectively disposed on the first sub-board and the second sub-board to form a same chip layout pattern.

8. The computing system of claim 7, wherein the chip layout pattern is a grid pattern.

9. The computing system of claim 8, wherein, viewed from a direction perpendicular to the sides of the first and second sub-boards, each of the second chips overlaps a respectively corresponding first chip and also overlaps with non-chip space on the first sub-board.

10. The computing system of claim 9, wherein the first chips and the second chips are instances of a same chip, wherein the first sub-board performs same computing functions as the second sub-board, and wherein the number of first chips is the same as the number of second chips.

11. The computing system of claim 1, wherein
the first chips are arranged to form first chip groups, each first chip group having at least two first chips disposed adjacently, and
the second chips is arranged to form second chip groups, each second chip group having at least two second chips disposed adjacently.

12. The computing system of claim 11, wherein at least a partial region of a second chip group is arranged not to overlap with a corresponding first chip group as viewed from a direction perpendicular to the sides of the first and second sub-boards.

13. The computing system of claim 1, wherein the first sub-board and the second sub-board are configured to share the cooling structure, wherein tops of the first chips face the cooling structure, and wherein tops of the second chips also face the cooling structure.

14. The computing system of claim 13, wherein the cooling structure is in contact with the tops of the first chips and with the tops of the second chips to cool the first chips and the second chips.

15. The computing system of claim 1, wherein the cooling structure comprises a flow path for a liquid or gaseous cooling fluid to flow or a heat exchange member for heat exchange.

16. An electronic device comprising:
a main board; and
sub-board units connected to the main board,
each sub-board unit comprising:
a cooling structure disposed between a first sub-board and a second sub-board;
the first sub-board electrically connected to the main board and comprising first chips arranged on a surface of the first sub-board that faces the cooling structure and that faces the second sub-board;
the second sub-board electrically connected to the main board and comprising second chips disposed on a surface of the second sub-board that faces the cooling structure and that faces the first sub-board; and
wherein the first sub-board and the second sub-board are arranged such that tops of the first chips and tops of the second chips face the cooling structure, and
wherein, from a direction perpendicular to the first and second sub-boards, at least a partial region a second chip among the second chips does not overlap with any of the first chips.

17. The electronic device of claim 16, wherein, from the direction perpendicular to the first and second sub-boards the second chips respectively correspond, positionally, to the first chips, and each second chip has at least a portion thereof that does not overlap its corresponding first chip.

18. The electronic device of claim 16, wherein the first chips and the second chips each have the same area, and wherein the area of each of regions where the first chips and the second chips only partially overlap with each other is less than or equal to one half of the area of each of the first and second chips.

19. The electronic device of claim 16, wherein
the first chips and the second chips are respectively arranged on the first sub-board and the second sub-board with a same grid pattern, and
from the direction perpendicular to the sides of the first and second sub-boards, each of the second chips overlaps with at least some space of the first sub-board that does not contain any of the first chips.

20. The electronic device of claim 16, wherein the electronic device is a supercomputer or a server.
